(19) United States
(12) Patent Application Publication
(10) Pub. No.: US 2025/0194286 A1
(43) Pub. Date: Jun. 12, 2025

(54) MULTI-LAYER CONTACT STACK, PHOTOVOLTAIC CELLS MADE THEREOF AND METHODS TO FORM THEM

(71) Applicant: NATIONAL UNIVERSITY OF SINGAPORE, Singapore (SG)

(72) Inventors: Nitin NAMPALLI, Singapore (SG); Shubham DUTTAGUPTA, Singapore (SG)

(73) Assignee: NATIONAL UNIVERSITY OF SINGAPORE, Singapore (SG)

(21) Appl. No.: 18/845,819

(22) PCT Filed: Mar. 13, 2023
(86) PCT No.: PCT/SG2023/050160

§ 371 Date: Sep. 10, 2024

(30) Foreign Application Priority Data
Mar. 11, 2022 (SG) 10202202509U

(51) Int. Cl. H10F 77/20; H10F 71/00

(52) U.S. Cl. CPC H10F 77/211; H10F 71/138; H10F 77/244

(57) ABSTRACT

Disclosed is a multi-layer contact structure comprising a semiconductor substrate, a terminal electrode, and a contact layer structure. The contact layer structure comprises a metal-containing carrier selective (MCS) layer, the contact layer structure being in intimate contact with the semiconductor substrate and the terminal electrode.

### TECHNICAL FIELD

The present invention relates to multi-layer contact structures comprising a contact layer structure in intimate contact with a semiconductor substrate and terminal electrode, wherein the contact layer structure comprises a metal-containing carrier selective (MCS) layer and a passivating tunnel (PT) layer between the MCS layer and semiconductor substrate. The present invention also relates to a photovoltaic cell including such a structure and a method for fabrication of the structure.

### BACKGROUND

Photovoltaic cells have become increasingly frequently used in offsetting fossil fuelled power production. Incumbent commercial solar cell technologies using front and rear terminal electrodes utilize contact layers that are thick or have significant absorption on the illuminated side of the cell, leading to low current output (J_{sc}) from the solar cell.

More recently, multi-layered contact solar cells have been proposed for increasing power output. Multi-layered contact solar cells in commercial production (e.g. classical heterojunction solar cells) use layers that have (a) high contact resistivity between layers, or (b) high layer resistivity, or (c) both. These lead to high overall internal series resistance (Rₛₑᵣᵢₑₛ) and consequently low power output from the solar cell.

Certain fabrication methods for multi-layered contact solar cells result in the unintentional and uncontrolled formation of layers near the surface of the silicon substrate. This uncontrolled layer formation leads to poor surface passivation and low carrier lifetime, ultimately leading to low voltage (V_{oc}) from the solar cell. With further regard to the fabrication of multi-layered contact solar cells, particular fabrication methods for multi-layered contact solar cells result in a change in compositional or behavioural properties of deposited layers or the unintentional formation of new layers over time due to redox reactions (thus occurring even in the dark) or due to carrier-induced effects (thus occurring only under illumination). These effects lead to the contact becoming suboptimal, leading to reduced V_{oc} and/or increased Rₛₑᵣᵢₑₛ over time. Such performance may fail industry-standard performance reliability testing standards and is unacceptable for commercial solar cells and module products.

Typical fabrication methods for multi-layered contacts require multiple layers to be applied using very different deposition methods. The use of multiple deposition methods can increase manufacturing costs. Even where the same deposition method is used for two or more layers, thermal evaporation or atomic layer deposition (ALD) is almost exclusively used. Both these methods have low deposition rates and in some cases, high material usage per unit of deposited layer thickness, resulting in process throughputs too low and operational costs too high for commercial production.

Some other fabrication process flows use multiple deposition systems. These flows require the transfer of samples from one deposition system to the next. If the ambient conditions during sample transfer are not controlled or are not suitable (such as air at atmospheric pressure), this can lead to the formation of unintentional layers or a change in the surface properties of the last deposited layer. Subsequent deposition of layers could then lead to overall suboptimal stack behaviour such as high contact resistivity or low passivation. Hence, an unprotected ambient could lead to a loss of process control over the overall stack properties. Ultimately, this could lead to low yield (high rates of quality check failure) in production, thereby increasing manufacturing costs.

It is desirable therefore to provide a multi-layer contact structure and a method for its fabrication, and a photovoltaic cell including such a structure, that avoids or ameliorates at least one of the aforementioned disadvantages or at least provides a useful alternative.

### SUMMARY

In view of aforementioned problems with known photovoltaic cells, structures and fabrication methods, the present disclosure proposes an interfacial contact structure for use with contacted solar cells with either full-area or partial-area electrodes. Solar cell architectures are also proposed, those cells being constructed using the abovementioned contact structure with either both terminal contacts on the rear of the cell or with terminal contacts on the front and rear of the cell. The interfacial contact structure consists of a multi-layered stack of, in some embodiments, up to four functional thin films. The interfacial contact structure is able to achieve a suitable compromise between high transparency, high carrier selectivity and high passivation, and represents an improvement over incumbent technologies for interfacial contact formation for solar cells. Also proposed are methods of forming this multi-layered contact structure on either the front side or the rear side of a solar cell using techniques suitable for industrial manufacturing.

In accordance with the present disclosure, there is provided a multi-layer contact structure comprising:
a semiconductor substrate;
a terminal electrode; and
a contact layer structure comprising:
   a metal-containing carrier selective (MCS) layer, the contact layer structure being in intimate contact with the semiconductor substrate and the terminal electrode.

In accordance with the present disclosure a photovoltaic cell comprising:
a first electrode;
a second electrode;
a first multi-layer contact structure as described above, connected to the first electrode; and
a contact layer structure connected to the second electrode.

Also disclosed herein is a method of fabricating a multi-layer contact structure in a deposition system comprising multiple deposition chambers, comprising maintaining the deposition chambers at a partial vacuum with a base pressure less than 10⁻³ bar.

The term “multi-layer contact stack” is generally used herein to refer to a structure having 2 to 4 layers, though will occasionally comprise a single layer. However, despite the use of the terms “multi-layer” and “stack”, the term “multi-layer contact stack” or “stack” may also refer to a contact layer structure comprising a single layer, such as a MCS layer, or multiple layers as dictated by context. In other circumstances, the term “contact structure” has been used to refer to a single layer or multiple layers and thus can be used interchangeably with the term “multi-layer contact stack”.

The term “intimate contact” between “A” and “B” refers to direct contact between “A” and “B” rather than indirect contact such as contact through another layer.

Advantageously, embodiments of the invention provide an interfacial contact stack (between a photovoltaic substrate and a terminal electrode layer) consisting of a stack of minimum 1, usually at least 2, and a maximum of 4 functional layers. Specific properties of layers and/or their interfaces are selected, that lead to high solar cell performance under illumination that is comparable to or better than incumbent technologies.

Advantageously, the composition and thickness range for each of the various layers is chosen based on properties required for a solar cell under illumination when applied to (a) only the front side of a solar cell (side that receives maximum illumination under normal operation), or (b) only the rear side of a solar cell (side that receives less illumination under normal operation).

Advantageously, some embodiments provide a method of depositing and modifying the properties of the layers within a single deposition system.

Advantageously, embodiments provide one or more metal-containing carrier selective layers. This provides improved optical transparency (compared to typical charge extraction layer(s) used in solar cells) with no/minimal increase in contact resistivity compared to typical solar cells.

Advantageously, the contact structure employs one or more passivating tunnel layers. This provides improved surface passivation of the substrate and low contact resistivity, leading to high device performance.

Advantageously, some embodiments employ a transparent conductive film layer, or layers. This layer, or these layers, improve long-term stability of passivation, composition and/or conductive properties of underlying layer or layers. This ensures minimal loss in device performance under real-world operating conditions. This layer, or these layers, can also provide enhanced lateral conductivity.

Advantageously, embodiments of the method for fabricating the contact stack (referred to herein as a contact structure) involve deposition of multiple layers using a single deposition system. This leads to minimal exposure of deposited layers to conditions outside of a controlled deposition environment prior to the deposition of the next layer. The follow on effect is stable performance, better process control, increased system throughput and potentially lower fabrication costs and material usage.

### BRIEF DESCRIPTION OF THE DRAWINGS

Some embodiments will now be described by way of non-limiting example only with reference to the accompanying drawings in which:

FIG. 1 illustrates a multi-layer contact structure, with embodiments for optimised for application to the front and rear of a photovoltaic cell.

FIG. 2 is a schematic diagram of a n-contact embodiment of the multi-layer contact structure of the present invention.

FIG. 3 is a schematic diagram of a p-contact embodiment of the multi-layer contact structure of the present invention.

FIG. 4 schematically shows three embodiments for multi-layer contact structures in accordance with present teachings.

FIG. 5 illustrates an all back electrode (ABC) embodiment for a multi-layer contact structure in accordance with present teachings.

FIG. 6 illustrates a system for forming the multi-layer contact structures described herein, using plasma enhanced chemical vapour deposition (PECVD) or ALD.

FIG. 7 illustrates a multi-modal system for forming the multi-layer contact structures described herein.

### DETAILED DESCRIPTION

Described below are multi-layer stacks that reduces use separate layers for each of cell current (J_{sc}, which depends on light transmittance through the layers), resistive losses (Rₛₑᵣᵢₑₛ, which depends on the thickness and conductivity of the layers) and passivation (V_{oc}, which requires low conductivity and high quality layers). This allows better control and therefore better performance in each of these 3 areas: transparency, resistance and passivation. The multi-layer stacks thereby reduce or avoid the tradeoff accepted by incumbent solar cell technologies that utilize low-bandgap carrier selective layers that makes the layers highly absorbing for light in the solar spectrum. Further, the use 1-2 contact layers constrains pre-existing cells to having to trade off between cell current, resistive losses and passivation.

Specific details of construction and methods that lead to ideal performance under illumination conditions and good process control are described, ensuring high suitability for solar cell manufacturing.

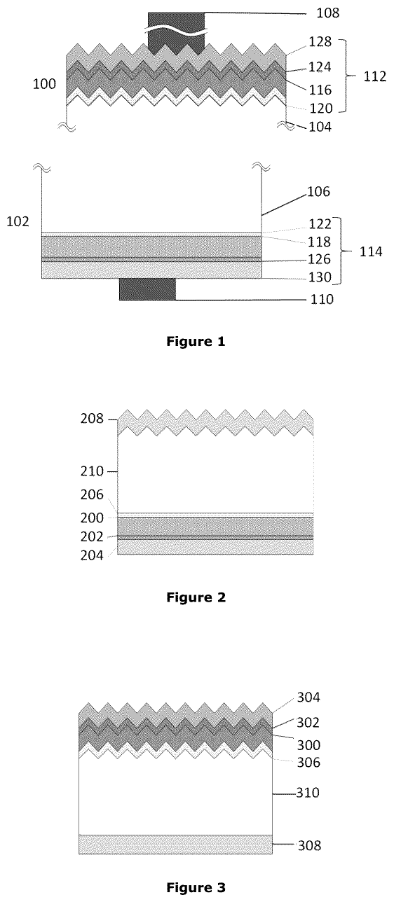

FIG. 1 shows embodiments of a multi-layer contact structure 100, 102. Multi-layer contact structure 100 is designed for application on the front side of a solar (photovoltaic) cell. Multi-layer contact structure 102 is designed for application on the rear side of a solar (photovoltaic) cell. The structure 100, 102 comprises a semiconductor substrate 104, 106, a terminal electrode 108, 110, and a contact layer structure 112, 114 (the large bracket surrounds the numerals used for the sublayers, rather than bounding a specific portion of the illustrated structures). The contact layer structure 112, 114 is in intimate, and thus direct, contact with the semiconductor substrate 104, 106 and the terminal electrode 108, 110.

The terminal electrode 108, 110 may provide a spike-through or non-spike through contact as dictated by the application requirements or fabrication equipment. Both can be achieved with the same processing methods (e.g. screen-printing of metal paste followed by curing). However, in the non-spike through contact, the metal paste will (a) not contain the components that cause spike-through and (b) be cured at a lower temperature. Typical spike-through contacts require special paste components and a curing temperature of >600 C.

The multi-layer contact structure 100 is suitable for use on the front (illuminated) side of the cell that are either thin or have low absorption, leading to improved J_{sc} and therefore improved device performance. The multi-layer contact structure 102 is suitable for use on the rear side of the cell.

The substrate 104, 106 may be n-type or p-type doped material such as Silicon. The surface of the substrate 104, 106 can be flat or planar, or textured. In textured embodiments, the surface texture can be any regular texture, such as upright pyramids or inverted pyramids or hemispherical concave features etched into the surface of the substrate. The surface texture can be large—e.g. >2 um—or small—e.g. 1-2 um. Etching can be performed using any appropriate process such as slow silicon etching (SSE) or saw damage etching (SDE).

The terminal electrode 108, 110 can be either a positive electrode or a negative electrode, with high conductivity. The terminal electrode 108, 110 may be form a semiconducting material (e.g. perform as a recombination layer). In such cases, the semiconducting material of the terminal electrode functions as a recombination junction in electrical contact with a second photovoltaic material that is different from the photovoltaic material described with reference to FIG. 1. or be substantially formed from metal. For example, the terminal electrode may comprise at least 80% by volume of metal, such as metal paste or pure metal.

For terminal electrodes that are metallic, the area of the electrode (i.e. of the contact surface of the electrode) that is in contact with the contact layer structure or contact stack may be 100%—i.e. full contact, such that the area of the electrode (i.e. the contact surface of the electrode) and contact layer structure (i.e. the surface of the contact layer structure that faces the electrode) is the same or the electrode has a larger area than that of the contact layer structure. In other embodiments, the electrode that may contact less than 100% of the area of the contact layer structure may be less than 100%—e.g. >90%, >60%, <10%, 0.5%-10% or some other proportion as required.

The multi-layer contact structure 112, 114 comprises a metal-containing carrier selective (MCS) layer 116, 118 and a passivating tunnel (PT) layer 120, 122 between the MCS layer 116, 118 and semiconductor substrate 104, 106. The MCS layer 116, 118 is to improve or provide carrier selectivity. The MCS layer 116, 118 may have the same doping or opposite doping to the substrate 104, 106. The passivating tunnel (PT) layer 120, 122 is for passivation. In some embodiments, the MCS layer 116, 118 is in intimate contact with both the substrate and terminal electrode. In such embodiments, there will be no passivation layer 120, 122.

For embodiments including the passivation layer 120, 122, that layer is intentionally formed and controlled to be in contact with the surface of the substrate 104, 106 (which may be, for example, silicon) using plasma enhanced chemical vapour deposition (PECVD) or other methods. The passivation layer 120, 122 can be formed from materials that exhibit high passivation qualities. Appropriate formation of, and material selection for, the passivation layer leads to high photovoltaic cell lifetime and therefore high V_{oc}, ultimately improving solar cell performance.

The contact layer structure 112, 114 of some embodiments further comprises one or both of a capping layer 124, 126 and transparent conductive film (TCF) 128, 130. The capping layer 124, 126 is used for stability and protection, and can enhance carrier selectivity. The TCF layer 128, 130 can be used for lateral charge transport.

The capping layer 124, 126 is in intimate contact with the MCS layer 116, 118. The MCS layer 116, 118 is therefore disposed between the semiconductor substrate 104, 106 and capping layer 124, 126. The capping layer 124, 126 is thus in contact with the MCS layer 116, 118 and either the terminal electrode 108, 110 or, if present, the TCF 128, 130. The TCF 128, 130 is disposed such that each other layer of the contact layer structure 112, 114 is between the TCF 128, 130 and substrate 104, 106. Thus, the TCF 128, 130 is in intimate contact with the terminal electrode 108, 110 and the MCS layer 116, 118 or, if present, the capping layer 124, 126.

While the multi-layer contact structures 100, 102 of FIG. 1 exhibit full area contact between the contact layer structures 112, 114 and terminal electrodes 108, 110, it will be appreciated that partial area contact may also be used. For full area contact, the contact area of the terminal electrode may be the same as the contact area of the contact layer structure. For partial area contact, the contact area of the terminal electrode may be less than the contact area of the contact layer structure.

The contact layer structure 112, 114 between a photovoltaic (semiconducting) substrate 104, 106 and a terminal electrode 108, 110 consists of a minimum of 1 layer and, in the embodiments described herein, a maximum of four layers. In single layer embodiments, the contact layer structure comprises one MCS layer that is in intimate contact with the substrate and the terminal electrode. In general, the contact layer structure will comprise a PT layer 120, 122, which is in intimate contact with the substrate 104, 106 and the MCS layer 116, 118.

As mentioned above, the contact layer structure 112, 114 is optimised depending on whether it is formed on the front or rear surface of the cell, and thus whether it is formed at the negative or positive electrode. When applied to the negative electrode (n-contact) as shown in FIG. 2, the contact layer structure may be flat or planar.

With further regard to the contact layer structure at the n-contact, the MCS 200 may be composed of a single layer. In other embodiments, the MCS is formed from a plurality of layers. The MCS 200 may be formed from a metal oxide or metal halide. The metal oxide material may be a stoichiometric or non-stoichiometric oxide of Ti, Hf, Ni, Ta, Zn, Cr, Ga or other metals. Similarly, the metal halide may be a stoichiometric or non-stoichiometric fluoride of Mg, Li, K, Cs, Ce or other metals, or a stoichiometric or non-stoichiometric chloride of Mg, Li, K, Cs, Ce or other metals.

The thickness of the MCS layer 200 may be any desired thickness, but is preferably 4-20 nm when used in combination with a CAP layer 202 or TCF layer 204. Where the MCS layer 200 is used independently of other layers in the contact layer structure, or with the PT layer 206 only, the layer thickness is 4-120 nm. As a result or proper MCS layer material selection, the contact resistivity to the substrate can be less than 0.1 Ω-cm².

Similarly, the PT layer 206 may be composed of a single layer or multiple layers. The PT layer 206 may be formed from one or more of the following materials: silicon thin films such as amorphous silicon (aSi), nano-crystalline silicon (nc-Si) or microcrystalline (μc-Si) or silicon compounds such as SiNx, SiONx, SiOx, or metal oxides such as stoichiometric or non-stoichiometric oxides of Al or other metals. The PT layer 206 may be 0.5-10 nm thick.

The CAP layer 202 may also be composed of a single layer or multiple capping layers as needed. The CAP layer 202 may be formed from of one or more of the following materials: metal halides such as stoichiometric or non-stoichiometric fluorides of Li, Ce or other metals, or low work-function metals (low work function relative to the silicon substrate) such as Ca, Mg, K, Yb, or other metals with lower work function relative to the silicon substrate, or metal oxides such as stoichiometric or non-stoichiometric oxides of Al or other metals. With appropriate material selection, the contact resistivity to the substrate is less than 0.1 Ω-cm².

The CAP layer 202 can be any appropriate thickness. In the present embodiments, it is 2-10 nm thick.

Lastly, for a contact layer structure formed at the n-contact, the TCF layer 204 may be composed of a single layer or multiple layers as required. The TCF layer 204 may be made from one or more of the following materials: structured forms of carbon such as carbon nanotubes, graphene, C₆₀, C₇₀ or other highly ordered forms of carbon, or metal oxides such as stoichiometric or non-stoichiometric oxides or Al or other metal, doped or non-doped oxides of In, Zn, Sn or other metals. The dopant species can be any appropriate species, such as one or more of Sn, Al, B, Zn, W, F, Ga. With appropriate material selection, the TCF layer 204 may have a bulk resistivity of less than 3 mΩ-cm, and facilitate control of contact resistivity to the substrate to be less than 0.1 Ω-cm².

The TCF layer 204 may have any appropriate thickness. In the present embodiments, the TCF layer 204 is 20-120 nm thick.

When formed at the n-contact, other layers 208, such as textured layers, can be formed on the opposite side of the substrate 210, for further optimisation.

When the contact layer structure is applied to the positive contact (p-contact) as shown in FIG. 3, the material selection should be optimised accordingly. The contact layer structure of such embodiments may be texture.

In embodiments formed at (including attached to) the p-contact, the MCS layer 300 is composed of a single layer. The MCS layer 300 may be one or more of the following class of materials: metal oxides or metal halides, metal sulphides. The metal oxides may be stoichiometric or non-stoichiometric oxides of Mo, W, V, Ni, Cu, Yb or other metals. The metal halides may be stoichiometric or non-stoichiometric fluorides of Mg, Li, K, Cs, Ce or other metals, or stoichiometric or non-stoichiometric chlorides of Mg, Li, K, Cs, Ce or other metals. The metal sulphides may be stoichiometric or non-stoichiometric fluorides of Cu, Ag or other metals. With appropriate material selection, the contact resistivity to the substrate is less than 0.1 Ω-cm².

The MCS layer 300 may have any appropriate thickness, such as 4-20 nm when used in combination with CAP layer 302 or TCF layer 304. The MCS layer 300 may be 4-120 nm when used independently or in combination with PT layer only 306—i.e. without the CAP layer 302 or TCF layer 304.

When the contact layer structure is formed at the p-contact, the PT layer 306 may be a single layer. The PT layer 306 may be made of a material and of a thickness similar to or the same as those set out above for the embodiment formed at the n-contact.

The CAP layer 302, if present, may be formed from one or more of the following materials: metal oxides, metal halides or low work-function metals or oxides. The metal oxides may be any appropriate oxide such as a stoichiometric or non-stoichiometric oxide of W, V, Ni, Cu, Yb, Cr, Al or other metals. Similarly, the halides may be any appropriate halides such as a stoichiometric or non-stoichiometric fluoride of Li, Ce or other metals, such as Ca, Mg, K, Yb, or other metals with lower workfunction relative to the silicon substrate. With appropriate material selection, contact resistivity to the substrate may be less than 0.1 Ω-cm².

The CAP layer 302 may have any appropriate thickness. In the embodiment shown, the CAP layer thickness is 2-10 nm thick.

The TCF 304 may comprise one or more layers. Moreover, the TCF 304 may be made of one or more of the following materials: structured forms of carbon such as one or more of carbon nanotubes, graphene, C₆₀, C₇₀ or other highly ordered forms of carbon, and metal oxides that are similar to or the same as those set out for the n-contact embodiment. Similarly, the thickness and bulk resistivity may be the same as those set out above for the n-contact embodiment. With appropriate material selection, the contact resistivity to the substrate may be less than 0.1 Ω-cm².

As with the n-contact embodiment of FIG. 2, further layers 308, such as un-textured or planar layers, may be formed on the opposite side of the substrate 310 to optimise properties of the contact layer structure.

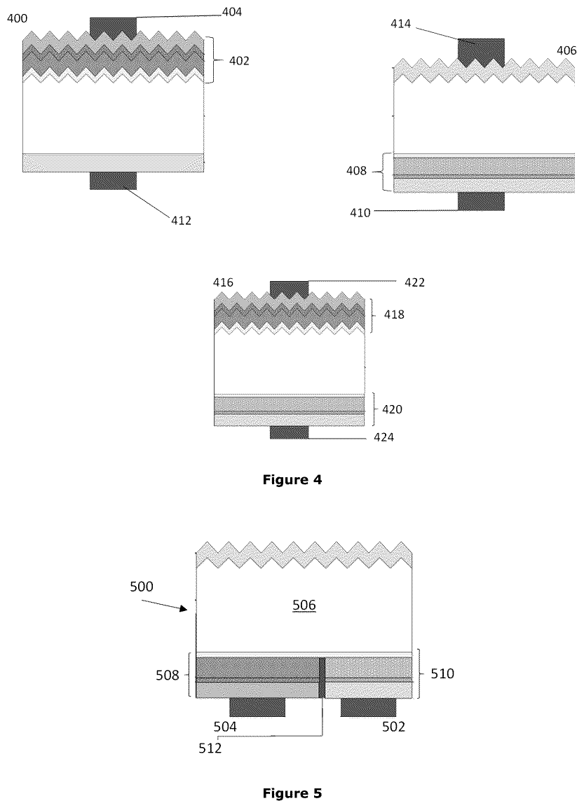

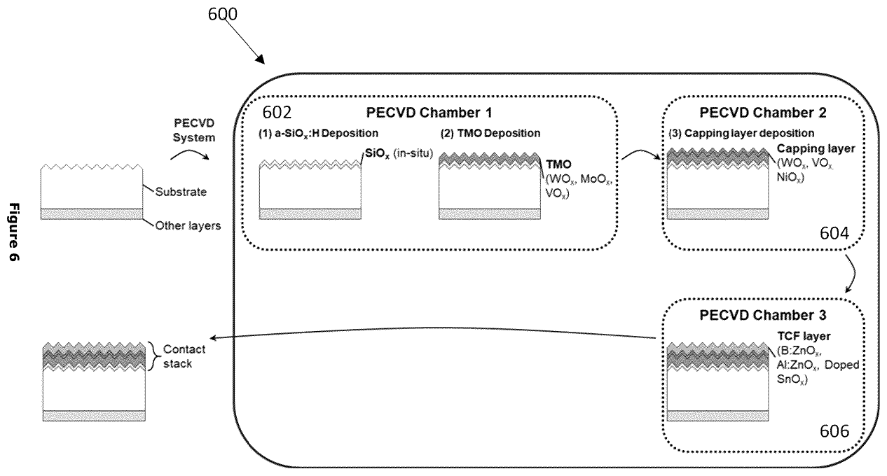

FIGS. 4 and 5 show photovoltaic cells, each of which includes a first electrode and second electrode, a first multi-layer contact structure connected to the first electrode and a second contact layer structure connected to the second electrode. The second contact layer structure may be another multi-layer contact structure as taught herein, or a different structure.

FIG. 4 shows three embodiments of solar cells (i.e. multi-layer contact structures), in which the terminals are at the front and back—i.e. front and rear—surfaces of the substrate. The cells are thus called “FAB” (front and back) cells.

In these embodiments, one or both terminal electrodes of the cell are connected to the photovoltaic substrate via a contact layer structure as taught herein. In embodiment 400, the contact layer structure 402 is applied only to the front electrode. In this embodiment, if the front electrode 404 is negative, the composition of the contact layer structure 402 is as described with reference to FIG. 2. If the front electrode 404 is positive, the composition of the contact layer structure or stack 402 is as described with reference to FIG. 3. In this embodiments, the other terminal electrode 412 is labelled for convenience.

In embodiment 406, the contact layer structure 408 is applied only to the front electrode. In this embodiment, if the front electrode 404 is negative, the composition of the contact layer structure 402 is as described with reference to FIG. 2. If the front electrode 404 is positive, the composition of the contact layer structure or stack 402 is as described with reference to FIG. 3. In this embodiments, the other terminal electrode 414 is labelled for convenience.

In embodiment 416 the contact layer structure 418, 420 is applied to both the front and rear electrodes 422, 424 respectively. In each case, if the electrode is negative then the composition of the contact layer structure connected to it will be as described with reference to FIG. 2. Oppositely, if the electrode is positive then the composition of the contact layer structure connected to it will be as described with reference to FIG. 3.

FIG. 5 shows an all back electrode (ABC cell) embodiment. In this embodiment, the ABC solar cell 500 has only rear terminal electrodes 502, 504 and both terminal electrodes 502, 504 are connected to the photovoltaic substrate 506 on the rear via the mechanism described with reference to FIG. 1. To insulate the two contact layer structures 508, 510 from each other, an insulating material 512 is present in the areas between the hole selective contact layer structure 508 (described with reference to FIG. 3) and the electron selective contact layer structure 510 (described with reference to FIG. 2).

The solar cells, multi-layer contact structures, and contact layer structures described with reference to FIGS. 1 to 5 use a passivating tunnel layer in intimate contact with the substrate semiconductor, an overlying carrier selective layer made of metallic compounds (specifically metal oxides or halides), an overlying capping layer to protect and/or stabilize the underlying layers, and a suitable transparent conducting film compatible with the underlying layer as well as with the terminal electrode of the solar cell. Such structures can reduce or avoid the tradeoff between cell current, resistive losses and passivation.

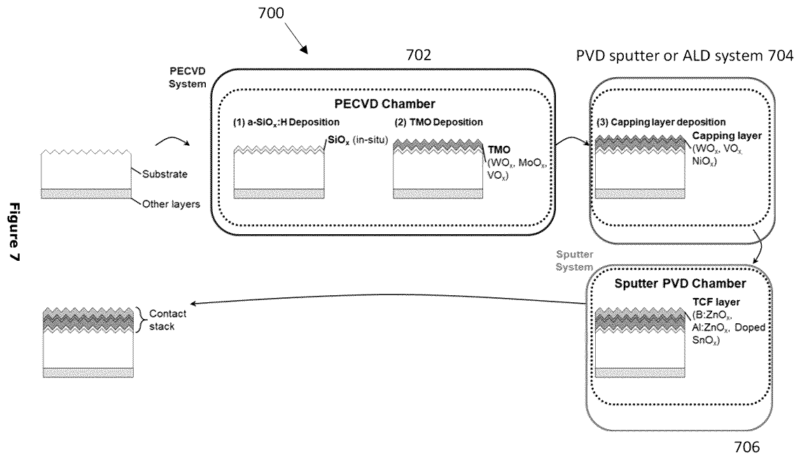

With reference to FIGS. 6 and 7, also described are systems to deposit and modify the properties of the various layers using a single fabrication system. With reference to FIG. 6, a deposition system 600 for fabricating a multi-layer contact structure is shown. The system 600 comprises multiple deposition chambers, and the method for its use involves maintaining the deposition chambers at a partial vacuum with a base pressure in a 10⁻³ bar range.

The system 600 comprises multiple deposition chambers 602, 604, 606 that use the same method of deposition—e.g. PECVD or ALD, or chambers may be switchable between the two deposition methods.

In some methods of operation of the system 600, only a single layer is deposited in any one chamber. In these methods, chamber conditions for the MCS layer and each of the potentially optional layers—namely the PT layer, CAP layer and TCF—are maintained as determined to be optimal for growth of the respective layer.

In other embodiments, more than one layer is deposited in one chamber. In such embodiments, where only two chambers of system 600 are utilised, the method of operation involves depositing the PT layer and MCS layer in the first chamber, and the MCS undergoes modification—e.g. plasma modification. The method further involves depositing the CAP layer in the second chamber, modifying the CAP layer (e.g. using plasma modification), depositing the TCF in the second chamber, modifying the TCF.

The modification steps can be performed to vary or change the properties of the layers. For example, the modification steps may change the surface energy of the underlying film (prior to depositing the next film). Surface adhesion may be controlled to improve adhesion of the 2 films. In some embodiments, the modification changes the workfunction of the surface layer of the underlying film. Workfunction modification can be used to control, e.g. reduce, the contact resistance between the two films. In some embodiments, modification can change the stoichiometry of the surface layer of the underlying film (e.g. oxygen content in the case of a metal oxide film) to make it more or less conductive or to improve the stability of the interface (temporal stability) to ensure it has the same performance over time.

The TCF can be modified via plasma treatment with either a reducing plasma (Hydrogen-rich=gas containing up to 20% of Hydrogen) or oxidizing plasma (oxygen-rich=ozone or O2 gas) or neutral plasma. Further the plasma modification can involve reactive plasmas (oxidizing or reducing types) or non-reactive plasmas (e.g. with noble gases like Ar or N2) or etching plasmas (to etch away the surface film of the TCF).

In embodiments where three chambers are utilised, the method of operation involves depositing the PT layer and MCS layer in the first chamber, and the MCS undergoes modification. The method also involves depositing and modifying the CAP layer in the second chamber, and depositing and modifying the TCF layer in the third chamber.

The system 600 is a single system which, in some cases, employs a single deposition chamber to deposit two or more layers. The preferred deposition method for the layers is CVD or PECVD, which has sufficiently high deposition rates and low material usage rates (low operational costs) to be suitable for commercial production. The controlled (partial vacuum) ambient conditions for embodiments employing multiple deposition chambers ensures transfer of samples between deposition chambers occurs in a controlled vacuum environment devoid of oxygen, moisture or other undesired ambient conditions. This preserves the properties of the last deposited layer and ensures that the properties or the stack (i.e. multi-layer contact structure) are sensitive to and therefore controllable via the process conditions in the deposition chambers. This increases the ability to control production quality, increasing yield and decreasing manufacturing costs.

In contrast to the single system 600 of FIG. 6, FIG. 7 uses multiple deposition systems 702, 704, 706. Each deposition system 702, 704, 706 comprises at least one chamber that uses a deposition method that is unique relative to the other deposition systems of system 700.

System 702 comprises one or more PECVD chambers. The PECVD chambers are maintained at a partial vacuum with a base pressure in the ˜10⁻³ bar range. To deposit one of the PT layer or the MCS layer, conditions are optimised for growth of the respective layer. To deposit both the PT layer and MCS layer in a single chamber, the conditions are sequentially optimised for growth of the PT layer and then for growth of the MCS layer.

System 704 comprises one or more chambers of the same deposition method (e.g. ALD) maintained at atmospheric pressure (or N2 ambient). For ALD deposition in system 704, a single layer (e.g. CAP or TCF) may be deposited in any one chamber, with growth conditions optimised for the respective layer. Where multiple layers are deposited in the chamber, growth conditions are sequentially optimised for growth of the respective layers—e.g. optimised for growth of the CAP layer and then the TCF.

For PVD sputtering in the system 704, in the event that only a single layer (e.g. CAP or TCF) is deposited in any one chamber, growth conditions are optimised for growth of the respective layer. If more than one layer is deposited, growth conditions are sequentially optimised for growth of one layer and then the next—e.g. optimised for growth of the CAP layer and then the TCF.

System 706 is an optional system comprises one or more chambers in which PVD sputtering occurs. The chamber or chambers are maintained at a base pressure in the ˜10⁻³ bar range. In the event that only a single layer (e.g. CAP or TCF) is deposited in any one chamber, growth conditions are optimised for growth of the respective layer. If more than one layer is deposited, growth conditions are sequentially optimised for growth of one layer and then the next—e.g. optimised for growth of the CAP layer and then the TCF.

In the above systems 600 and 700 and methods for their operation, PECVD can be used in a single system for depositing two to four layers. In other embodiments, PECVD is used to deposit two or three layers, with sputter being used to deposit a layer, or ALD being used to deposit one or two layers. In other embodiments, PECVD is used for one to two layers, ALD for one layer and sputter for one layer. Other combinations and high-throughput vacuum methods (e.g. linear evaporation) may also be used.

A multi-layer contact structure produced in system 600 or 700 is a carefully engineered stack of layers with optimal electrical properties, low inter-layer contact resistivity and appropriate thickness to reduce overall contact resistivity as well as individual layer resistivity. The net effect is a decrease in Rₛₑᵣᵢₑₛ when compared with previous contact structures, leading to high solar cell power output. The multi-layer contact structures produced by system 600 or 700 is also designed to stabilize the properties of the deposited layers. For example: the optional capping layer and/or intentionally modifying the properties of the terminal face of the layer can prevent or minimize redox reactions; selecting a suitable combination of materials can avoid redox reactions altogether; materials and stacks can be selected or engineered for stable contact performance under illuminated conditions. As a result, the final solar cell device has sufficiently stable performance with a power output that does not decrease substantially over time. This makes cells utilizing such contacts more likely to pass industry-standard performance reliability testing standards and be more suitable for commercial use.

In this specification and the claims that follow, unless stated otherwise, the word “comprise” and its variations, such as “comprises” and “comprising”, imply the inclusion of a stated integer, step, or group of integers or steps, but not the exclusion of any other integer or step or group of integers or steps.

The various embodiments and variations thereof illustrated in the accompanying Figures and/or described herein are merely exemplary and are not intended to limit the scope of the invention. It is to be appreciated that numerous variations of the invention have been contemplated as would be obvious to one of ordinary skill in the art with the benefits of this disclosure. Rather, the scope and breadth afforded this document should only be limited by the claims provided herein while applying either the plain meaning to each of the terms and phrases in the claims or the meaning clearly and unambiguously provided in this application.

References in this specification to any prior publication, information derived from any said prior publication, or any known matter are not and should not be taken as an acknowledgement, admission or suggestion that said prior publication, or any information derived from this prior publication or known matter forms part of the common general knowledge in the field of endeavour to which the specification relates.

1. A multi-layer contact structure comprising:
a semiconductor substrate;
a terminal electrode; and
a contact layer structure comprising:
a metal-containing carrier selective (MCS) layer, the contact layer structure being in intimate contact with the semiconductor substrate and the terminal electrode.

2. The multi-layer structure of claim 1, further comprising a passivating tunnel (PT) layer between the MCS layer and semiconductor substrate.

3. The multi-layer structure of claim 1, wherein the contact layer structure has partial area contact with the terminal electrode.

4. The multi-layer contact structure of claim 1, wherein the contact layer structure further comprises one or both of a capping layer and transparent conductive film (TCF):
wherein the capping layer, if present, is in intimate contact with the MCS layer, the MCS layer being disposed between the semiconductor substrate and capping layer; and
wherein the TCF, if present, is disposed such that each other layer of the contact layer structure is between the TCF and substrate.

5. The multi-layer contact structure of claim 1, wherein the MCS layer is between 4 nm and 120 nm thick.

6. The multi-layer contact structure of claim 5, wherein the MCS layer is between 4 nm and 20 nm thick.

7. The multi-layer contact structure of claim 1, wherein the MCS layer comprises or constitutes a metal oxide or metal halide.

8. The multi-layer contact structure of claim 3, wherein the PT layer is between 0.5 nm and 7 nm thick.

9. The multi-layer contact structure of claim 4, wherein the capping layer, if present, is between 2 nm and 10 nm thick and the TCF, if present, is between 20 nm and 120 nm thick.

10. A photovoltaic cell comprising:
a first electrode;
a second electrode;
a first multi-layer contact structure according claim 1, connected to the first electrode; and
a contact layer structure connected to the second electrode.

11. The photovoltaic cell of claim 10, wherein the contact layer structure is part of a second multi-layer structure according to any one of claims 1 to 7, the substrate of the first multi-layer structure also being the substrate of the second multi-layer structure.

12. The photovoltaic cell of claim 10, wherein the first electrode is a front electrode and the first multi-layer contact structure is textured.

13. The photovoltaic cell of claim 11, wherein the PT layer of the first multi-layer contact structure is the PT layer of the second multi-layer contact structure, and wherein the MCS of the first multi-layer contact structure is hole selective and the MCS of the second multi-layer contact structure is electron selective.

14. A method of fabricating a multi-layer contact structure in a deposition system comprising multiple deposition chambers, comprising maintaining the deposition chambers at a partial vacuum with a base pressure in a 10⁻³ bar range.

15. The method of claim 14, further comprising operating each of the multiple deposition chambers using a common deposition method.

16. The method of claim 15, wherein the common deposition method comprises either plasma-enhanced CVD or atomic layer etching.

17. The method of claim 14, wherein each deposition chamber deposits a single layer of the multi-layer contact structure.

18. The method of claim 15, wherein operating each of the multiple deposition chambers using a common deposition method comprises:
operating a first chamber of the multiple deposition chambers to deposit a passivating tunnel (PT) layer and a metal-containing carrier selective (MCS) layer; and
performing plasma modification of the MCS layer.

19. The method according to claim 18, wherein operating each of the multiple deposition chambers using a common deposition method comprises:
operating a second chamber of the multiple deposition chambers to deposit a capping layer and a transparent conductive film (TCF);
performing plasma modification of the capping layer; and
modifying the TCF.

20. The method of claim 14, wherein each chamber performs one of plasma-enhanced chemical vapour deposition, atomic layer deposition and sputter physical vapour deposition.
